(19) United States
(12) Patent Application Publication
(10) Pub. No.: US 2011/0042802 A1
(43) Pub. Date: Feb. 24, 2011

(54) Semiconductor device, external connection terminal, method of manufacturing semiconductor device, and method of manufacturing external connection terminal

(75) Inventor: Fumiyoshi Kawashiro, Kanagawa (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: NEC Electronics Corporation, Kawasaki-shi (JP)

(21) Appl. No.: 12/805,203

(22) Filed: Jul. 19, 2010

(30) Foreign Application Priority Data
Aug. 20, 2009 (JP) 2009-191489

(51) Int. Cl. H01L 23/48; H01L 21/44

(52) U.S. Cl. 257/735; 438/611; 257/E23.01; 257/E21.476; 977/755; 977/932

(57) ABSTRACT

A semiconductor device includes an electrode pad and an external connection terminal. The external connection terminal contains Sn equal to or more than 50 wt %, Sn and Pb equal to or more than 90 wt % in total, or Pb equal to or more than 85 wt %, and the surface thereof is coated with an Au layer. The thickness of the Au layer is preferably equal to or more than 10 nm and equal to or less than 1 μm. The weight of the Au layer is preferably equal to or less than 0.6% of the weight of the external connection terminal.

The application is based on Japanese patent application No. 2009-191489, the content of which is incorporated hereinto by reference.

### BACKGROUND

1. Technical Field

The present invention relates to a semiconductor device in which an interconnect and an electrode pad are connected using an external connection terminal, the external connection terminal, a method of manufacturing the semiconductor device, and a method of manufacturing the external connection terminal.

2. Related Art

One of the structures for mounting a semiconductor device, in which a semiconductor chip is attached on an interconnect substrate, in a circuit substrate includes a ball grid array (BGA) structure. The BGA structure is configured so that the external connection terminal, such as solder balls, is attached to the electrode pad of the interconnect substrate, and this external connection terminal is connected to the interconnect of the circuit substrate.

In addition, the structures for attaching the semiconductor chip to the interconnect substrate include a flip-chip. The flip-chip is configured so that the external connection terminal, such as solder bumps, is formed in the electrode pad of the semiconductor chip, and this external connection terminal is connected to the interconnect of the interconnect substrate.

In such structures, the connection reliability of the electrode pad and the interconnect is dependent on the external connection terminal to a great extent. For example, PCT Japanese translation of PCT international application NO. 2008-518791, Japanese Unexamined patent publication NO. 2007-175776, Pamphlet of International Publication NO. WO 01/080611, and Japanese Unexamined patent publication NO. 2007-260779 disclose that the composition of the external connection terminal is contrived for the purpose of securing a low melting point, wettability, and a bonding strength or the like.

When the external connection terminal is bonded to the interconnect or the electrode pad, the external connection terminal is heated and melted. In this heating process, since the surface of the external connection terminal is thermally oxidized before the external connection terminal is melted, an oxidized film is grown on the surface of the external connection terminal. Since the melting point of the metal oxidized film is generally high, even in the case where a portion which is not oxidized in the external connection terminal is melted, the oxidized film located at the surface of the external connection terminal remains unmelted. For this reason, the external connection terminal is in a state where the melted inside portion thereof is covered by the surface oxidized film, and thus the melted portion is not in contact with the interconnect or the electrode pad until this oxidized film is broken. When the oxidized film is grown and becomes thicker, the oxidized film is difficult to break, and thus it is difficult for the melted portion in the external connection terminal to be in contact with the interconnect or the electrode pad. Therefore, there has been a case where connection reliability of the external connection terminal and the interconnect or the electrode pad is lowered.

### SUMMARY

In one embodiment, there is provided a semiconductor device including: an electrode pad; and an external connection terminal connected to said electrode pad, wherein said external connection terminal contains Sn which is equal to or more than 50 wt %, Sn and Pb which are equal to or more than 90 wt % in total, or Pb which is equal to or more than 85 wt %, and the surface of the external connection terminal is coated with an Au layer.

According to the invention, the surface of the external connection terminal is coated with the Au layer. Au does not oxidize easily. Even when the external connection terminal is heated for the purpose of being melted, the corresponding temperature is a relatively low temperature (for example, 180° C. to 280° C. or so), and thus, typically, there is no case where a thermally-oxidized film is formed on the Au layer of the surface of the external connection terminal. In addition, Au forms a low melting point alloy with any of Sn and Pb, and thus when the external connection terminal is heated and melted the Au layer is easily broken. For this reason, when the surface of the external connection terminal is coated with the Au layer, it is easy for the melted external connection terminal to be in contact with the interconnect. Therefore, it is possible to suppress connection reliability of the external connection terminal and the interconnect from being lowered.

In another embodiment, there is provided an external connection terminal, connected to an electrode pad of an interconnect substrate or a semiconductor device, that contains Sn which is equal to or more than 50 wt %, Sn and Pb which are equal to or more than 90 wt % in total, or Pb which is equal to or more than 85 wt %, the surface of the external connection terminal is coated with an Au layer.

According to the invention, when the external connection terminal is melted and connected to the interconnect or the electrode pad, it is possible to suppress the surface oxidized film of the external connection terminal from becoming thick. For this reason, it is easy for the melted external connection terminal to be in contact with the interconnect or the electrode pad, to thereby allow lowering of connection reliability of the interconnect or the electrode pad and the external connection terminal to be suppressed.

In further another embodiment, there is provided a method of manufacturing a semiconductor device, including: attaching an external connection terminal containing Sn which is equal to or more than 50 wt %, Sn and Pb which are equal to or more than 90 wt % in total, or Pb which is equal to or more than 85 wt % to an electrode pad; coating the surface of said external connection terminal with an Au layer; and contacting said external connection terminal with an interconnect of a substrate and melting said external connection terminal to thereby connect said electrode pad and said interconnect through said external connection terminal.

In still further another embodiment, there is provided a method of manufacturing an external connection terminal, including: manufacturing the external connection terminal containing Sn which is equal to or more than 50 wt %, Sn and Pb which are equal to or more than 90 wt % in total, or Pb which is equal to or more than 85 wt %; and coating the surface of said external connection terminal with an Au layer.

According to the invention, it is possible to suppress connection reliability of the interconnect or the electrode pad and the external connection terminal from being lowered.

### BRIEF DESCRIPTION OF THE DRAWINGS

The above and other objects, advantages and features of the present invention will be more apparent from the following description of certain preferred embodiments taken in conjunction with the accompanying drawings, in which:

FIGS. 1A and 1B are cross-sectional views for describing a method of manufacturing a semiconductor device according to a first embodiment;

FIGS. 2A and 2B are cross-sectional views for describing a method of mounting the semiconductor device shown in FIG. 1B in a circuit substrate;

FIG. 3 is a schematically cross-sectional view illustrating the whole semiconductor device in a state of FIG. 2B;

FIG. 4 is a cross-sectional view of the semiconductor device according to a second embodiment;

FIGS. 5A and 5B are cross-sectional views for describing a method of mounting a semiconductor chip in an interconnect substrate;

FIGS. 6A and 6B are cross-sectional views for describing the method of mounting the semiconductor chip in the interconnect substrate;

FIG. 7 is a cross-sectional view illustrating the whole semiconductor device according to a third embodiment;

FIGS. 8A to 8C are diagrams illustrating a method of manufacturing the external connection terminal and the semiconductor device according to a fourth embodiment; and

FIG. 9 is a diagram illustrating the method of manufacturing the external connection terminal and the semiconductor device according to the fourth embodiment.

### DETAILED DESCRIPTION

The invention will be now described herein with reference to illustrative embodiments. Those skilled in the art will recognize that many alternative embodiments can be accomplished using the teachings of the present invention and that the invention is not limited to the embodiments illustrated for explanatory purposes.

Hereinafter, the embodiment of the invention will be described with reference to the accompanying drawings. In all the drawings, like elements are referenced by like reference numerals and descriptions thereof will not be repeated.

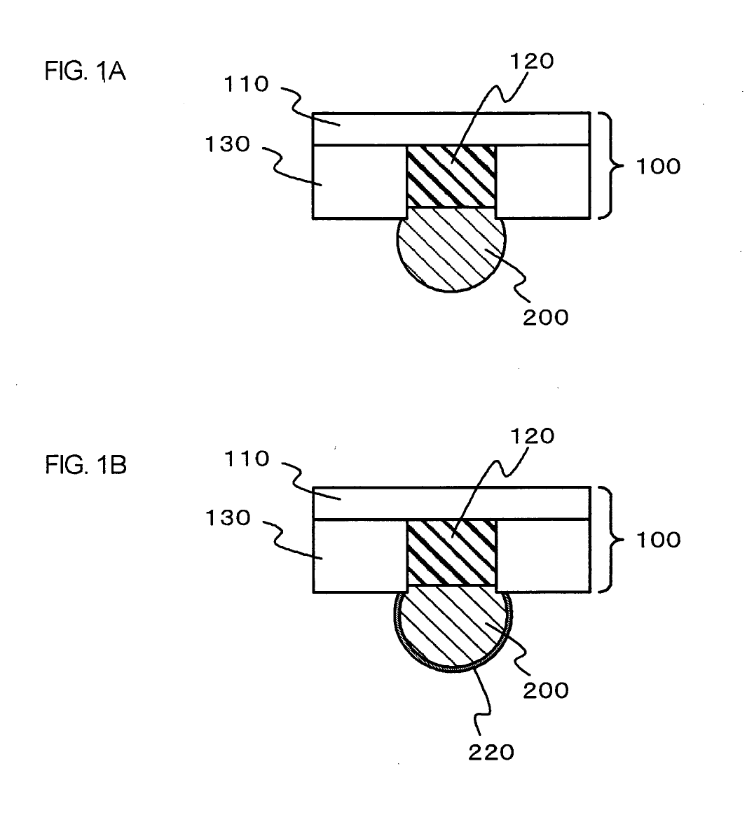

FIGS. 1A and 1B are cross-sectional views for describing the method of manufacturing the semiconductor device according to the first embodiment. The semiconductor device according to the embodiment includes an electrode pad 120 and an external connection terminal 200, as shown in FIG. 1B. The external connection terminal 200 contains Sn equal to or more than 50 wt %, Sn and Pb equal to or more than 90 wt % in total, or Pb equal to or more than 85 wt %, and the surface thereof is coated with an Au layer 220. The thickness of the Au layer 220 is preferably equal to or more than 10 nm and equal to or less than 1 μm. The weight of the Au layer 220 is preferably equal to or less than 0.6% of the weight of the external connection terminal 200. Meanwhile, the external connection terminal 200 may be a solder ball, and may be a solder bump.

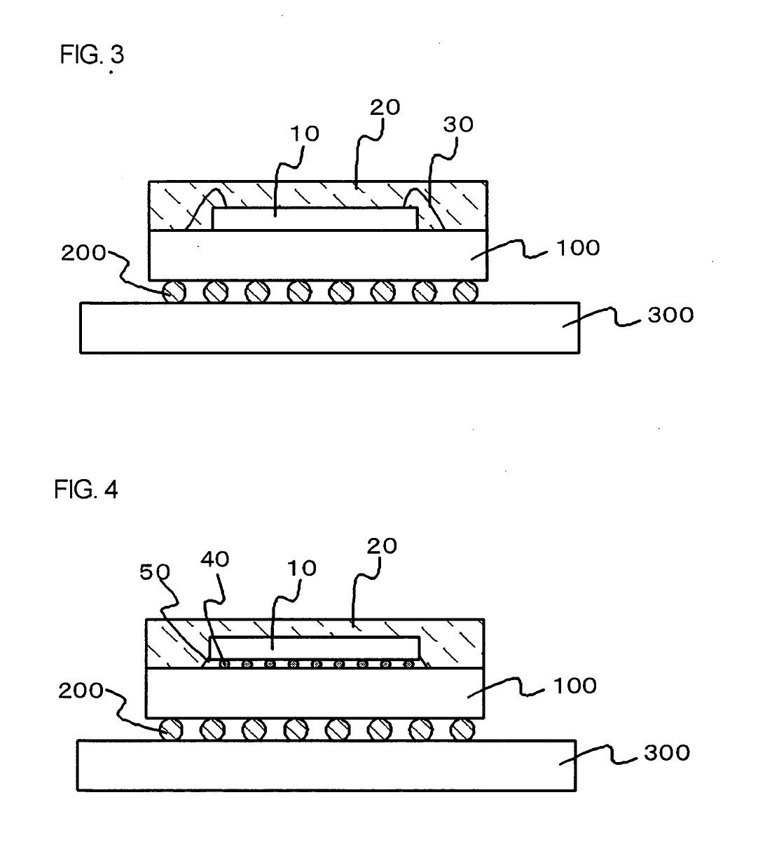

In the embodiment, the electrode pad 120 is made and provided in the interconnect substrate 100. A semiconductor chip 10 as described later with reference to FIG. 3 is mounted in one surface of the interconnect substrate 100, and the electrode pad 120 is made of Cu and formed in the other surface of the interconnect substrate 100. The external connection terminal 200 contains Sn equal to or more than 90 wt %, Ag equal to or more than 1 wt % and equal to or less than 4 wt %, and Cu equal to or more than 0.1 wt % and equal to or less than 0.8 wt %. When such a composition is used, it is possible to improve wettability of the external connection terminal 200 with respect to the interconnect or the electrode pad 120.

In this case, it is preferable that the external connection terminal 200 further contains at least one of Ni equal to or more than 0.015 wt % and equal to less than 0.08 wt %, and Co equal to or more than 0.002 wt % and equal to or less than 0.02 wt %. In this manner, at the time of bonding the external connection terminal 200 to the interconnect or the electrode pad 120, it becomes possible to improve the impact resistance and thermal fatigue property of the bonding portion.

In addition, it is preferable that the external connection terminal 200 further contains at least one of P equal to or more than 0.0002 wt % and equal to or less than 0.01 wt %, and Ge equal to or more than 0.002 wt % and equal to or less than 0.01 wt %. This can suppress a naturally-oxidized film from being formed on the surface of the external connection terminal 200.

Next, the above-mentioned method of manufacturing the semiconductor device, and a method of using this semiconductor device will be described. First, as shown in FIG. 1A, the interconnect substrate 100 is prepared, and in the interconnect substrate 100, a solder resist layer 130 and the electrode pad 120 are formed on an insulating base material 110. The electrode pad 120 is exposed from an opening which is provided in the solder resist layer 130.

Next, the external connection terminal 200, for example, a solder ball is attached to the electrode pad 120. In this step, the Au layer 220 is not formed on the surface of the external connection terminal 200.

Meanwhile, in this state, the semiconductor chip 10 shown in FIG. 3 is mounted in one surface of the interconnect substrate 100. The whole surface of the semiconductor chip 10 is coated with a resin layer 20 shown in FIG. 3.

Next, as shown in FIG. 1B, the Au layer 220 is formed on the surface of the external connection terminal 200. A method of forming the Au layer 220 includes an electroless plating method and an electroplating method.

When the electroless plating method is used, it is possible to form the Au layer 220 by immersing the interconnect substrate 100 and the external connection terminal 200 in a plating solution. Meanwhile, since the semiconductor chip 10 shown in FIG. 3 is coated with the resin layer 20 shown in FIG. 3, and the other surface of the interconnect substrate 100 is coated with the solder resist layer 130, formation of the Au layer 220 in unnecessary places is suppressed.

When the electroplating method is used, an extraction interconnect for applying a voltage to the electrode pad 120 is formed in the interconnect substrate 100. The interconnect substrate 100 and the external connection terminal 200 are immersed in a plating solution, and a voltage is applied to the above-mentioned extraction interconnect, thereby allowing the Au layer 220 to be formed.

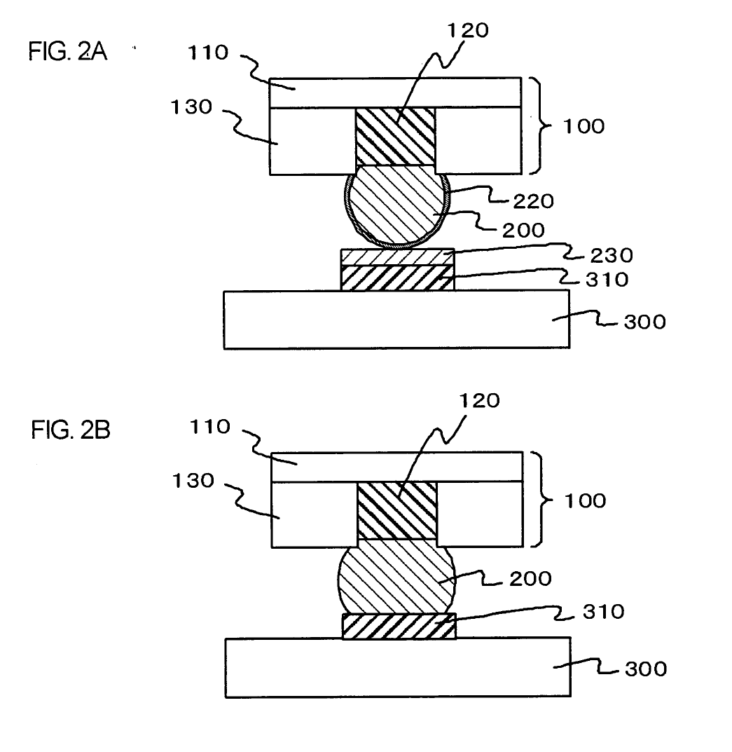

FIGS. 2A and 2B are cross-sectional views for describing a method of mounting the semiconductor device shown in FIG. 1B in a circuit substrate 300. An interconnect 310 to be connected to the electrode pad 120 is formed in the circuit substrate 300.

First, as shown in FIG. 2A, a solder paste 230 is applied to the surface of the interconnect 310. Then, a flux 202 instead of the solder paste 230 may be applied to the surface of the interconnect 310. Next, the external connection terminal 200 and the Au layer 220 are brought in contact with the solder paste 230 (or the flux 202).

Next, as shown in FIG. 2B, the external connection terminal 200, the Au layer 220, and the solder paste 230 (or the flux 202) are heated and melted, and then cooled. Hereby, the external connection terminal 200 is bonded to both the interconnect 310 and the electrode pad 120, and the interconnect 310 is connected to the electrode pad 120 through the external connection terminal 200. Meanwhile, in this process, the Au layer 220 and the solder paste 230 (or the flux 202) are melted in the external connection terminal 200.

FIG. 3 is a schematically cross-sectional view illustrating the whole semiconductor device in the state of FIG. 2B. The semiconductor chip 10 is mounted in one surface of the interconnect substrate 100. A bonding wire 30 is used in the connection of the semiconductor chip 10 and the interconnect substrate 100. The resin layer 20 is formed on one surface of the interconnect substrate 100. The resin layer 20 is used to coat the semiconductor chip 10 and the bonding wire 30.

The external connection terminal 200 is provided in the other surface of the interconnect substrate 100. The external connection terminal 200 is connected to the interconnect substrate 100 and the circuit substrate 300.

Next, the operation and the advantage of the embodiment will be described. According to the embodiment, before the external connection terminal 200 is bonded to the interconnect 310 of the circuit substrate 300, the surface of the external connection terminal 200 is coated with the Au layer 220. Au does not oxidize easily. For this reason, even when the external connection terminal 200 is heated for the purpose of being melted, the corresponding temperature is a relatively low temperature (for example, 180° C. to 280° C. or so), and thus, typically, there is no case where a thermally-oxidized film is formed on the Au layer 220 of the surface of the external connection terminal 200. In addition, it is easy for Au to form an alloy with any of Sn and Pb, and thus when the external connection terminal 200 is heated and melted the Au layer 220 is easily broken. Therefore, the melted external connection terminal 200 is easily brought into contact with the interconnect 310, and the lowering of the connection reliability of the interconnect 310 with the external connection terminal 200 is suppressed. The Au layer 220 may be equal to or more than 10 nm for the purpose of producing such an effect.

In addition, before the Au layer 220 is formed in the external connection terminal 200, there is a case where the naturally-oxidized film is formed on the surface of the external connection terminal 200. However, the naturally-oxidized film is coated with the Au layer 220, and thus even when the external connection terminal 200 is heated for the purpose of being melted, the naturally-oxidized film is not grown. For this reason, when the external connection terminal 200 is heated and a portion other than the naturally-oxidized film is melted, the naturally-oxidized film is easily broken. When the naturally-oxidized film is broken, melted materials containing Sn and Pb are brought into contact with the Au layer 220, and thus the Au layer 220 is easily broken. Therefore, the melted external connection terminal 200 is easily brought into contact with the interconnect 310, and the lowering of the connection reliability of the interconnect 310 with the external connection terminal 200 is suppressed.

In addition, the surface of the external connection terminal 200 is coated with the Au layer 220. When the external connection terminal 200 is heated and melted, the starting point of the melting becomes the interface between the external connection terminal 200 and the Au layer 220. For this reason, the melting initiation temperature of the external connection terminal 200 becomes low compared to the case where Au is added to the whole external connection terminal 200.

In addition, when the external connection terminal 200 is connected to the circuit substrate 300, the Au layer 220 is melted in the external connection terminal 200. In the case where the thickness of the Au layer 220 is equal to or less than 1 μm, it is possible to suppress the Au concentration of the external connection terminal 200 from becoming excessively high. In addition, even in the case where the weight of the Au layer 220 is equal to or less than 0.6% of the weight of the external connection terminal 200, it is possible to suppress the Au concentration of the external connection terminal 200 from becoming excessively high.

FIG. 4 is a cross-sectional view of the semiconductor device according to the second embodiment, and a diagram equivalent to FIG. 3 according to the first embodiment. This semiconductor device is the same as that of the first embodiment except in the following respect.

First, the semiconductor chip 10 is flip-chip mounted in the interconnect substrate 100, and a solder bump 40 is used in connection of the semiconductor chip 10 with the interconnect substrate 100. In addition, a connection portion of the semiconductor chip 10 with the interconnect substrate 100 is sealed by a sealing resin 50.

This method of manufacturing the semiconductor device is the same as that of the first embodiment with respect to the processes after the semiconductor chip 10 is mounted in the interconnect substrate 100, and hence the description thereof will not be repeated.

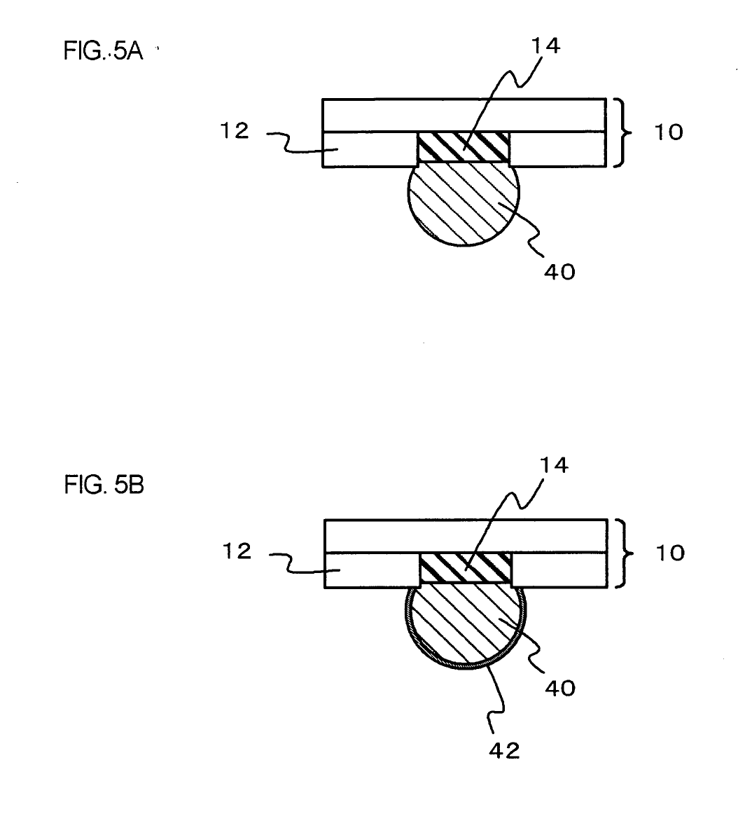

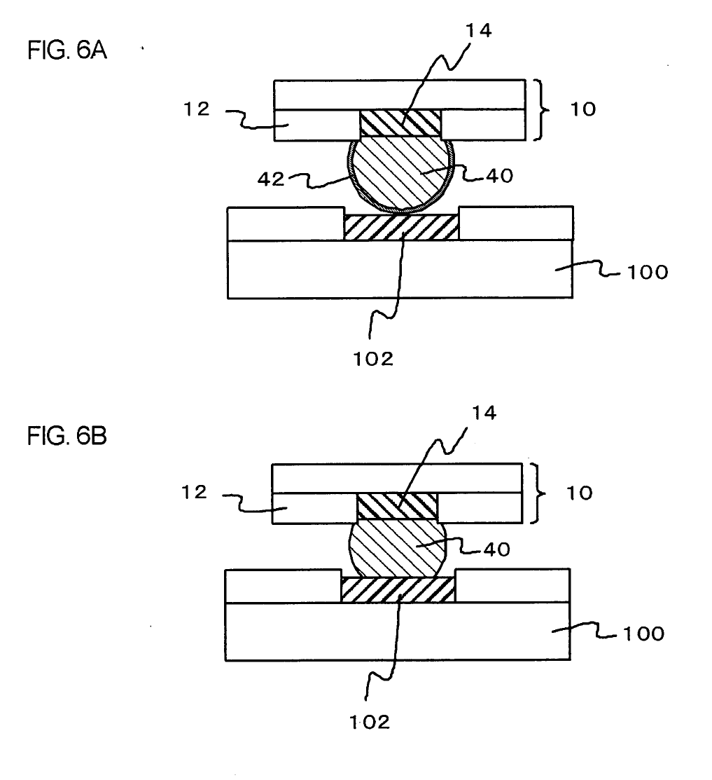

FIGS. 5A and 5B and FIGS. 6A and 6B are cross-sectional views for describing methods of mounting the semiconductor chip 10 in the interconnect substrate 100. First, as shown in FIG. 5A, the semiconductor chip 10 is prepared, and a protective film 12 and an electrode pad 14 are formed on the surface of the semiconductor chip 10. The electrode pad 14 is exposed from an opening provided in the protective film 12.

Next, the solder bump 40 is formed in the electrode pad 14. The solder bump 40 contains Pb equal to or more than 85 wt %. Meanwhile, the solder bump 40 may contain Sn of 50 wt %, may contain Sn and Pb equal to or more than 90 wt % in total, and may contain Pb equal to or more than 85 wt %.

Next, as shown in FIG. 5B, an Au layer 42 is formed on the surface of the solder bump 40. A method of forming the Au layer 42 is the same as the method of forming the Au layer 220 in the first embodiment.

Next, as shown in FIG. 6A, the solder bump 40 and the Au layer 42 are brought in contact with an electrode pad 102 of the interconnect substrate 100. Here, before the solder bump 40 and Au layer 42 are brought connect with the electrode pad 102 of the interconnect substrate 100, the solder paste 230 (or the flux 202) is applied to the surface of the interconnect 310 as the first embodiment.

Next, as shown in FIG. 6B, the solder bump 40 and the Au layer 42 are heated and melted, and then cooled. Hereby, the solder bump 40 is bonded to both the electrode pad 14 and the electrode pad 102, and the electrode pads 14 and 102 are connected to each other through the solder bump 40. Meanwhile, in this process, the Au layer 42 is melted in the solder bump 40.

In the embodiment, it is also possible to obtain the same effect as that of the first embodiment. In addition, even when the semiconductor chip 10 is mounted in the interconnect substrate 100, the above-mentioned effect can be obtained.

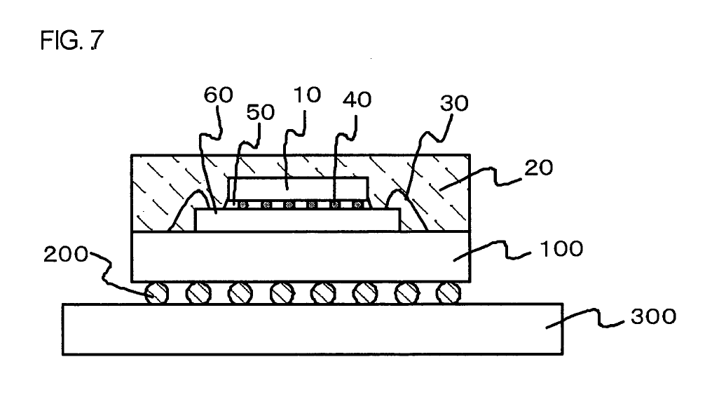

FIG. 7 is a cross-sectional view illustrating the whole semiconductor device according to the third embodiment, and a diagram equivalent to FIG. 4 in the second embodiment. This semiconductor device is the same as that of the second embodiment except in the following respect.

First, the semiconductor chip 10 is flip-chip mounted in a semiconductor chip 60. The solder bump 40 is used in the connection of the semiconductor chip 10 with the semiconductor chip 60. A method of connecting the semiconductor chips 10 and 60 using the solder bump 40 is the same as the method of connecting the semiconductor chip 10 with the interconnect substrate 100 in the second embodiment. The connection portion of the semiconductor chip 10 with the semiconductor chip 60 is sealed by the sealing resin 50.

The semiconductor chip 60 is mounted on the interconnect substrate 100. The semiconductor chip 60 and the interconnect substrate 100 are connected to each other by the bonding wire 30. The semiconductor chips 10 and 60, and the bonding wire 30 are covered by the resin layer 20.

In the embodiment, it is also possible to obtain the same effect as that of the second embodiment. Meanwhile, in the embodiment, the semiconductor chip 10 and the interconnect substrate 100 may be connected by the bonding wire.

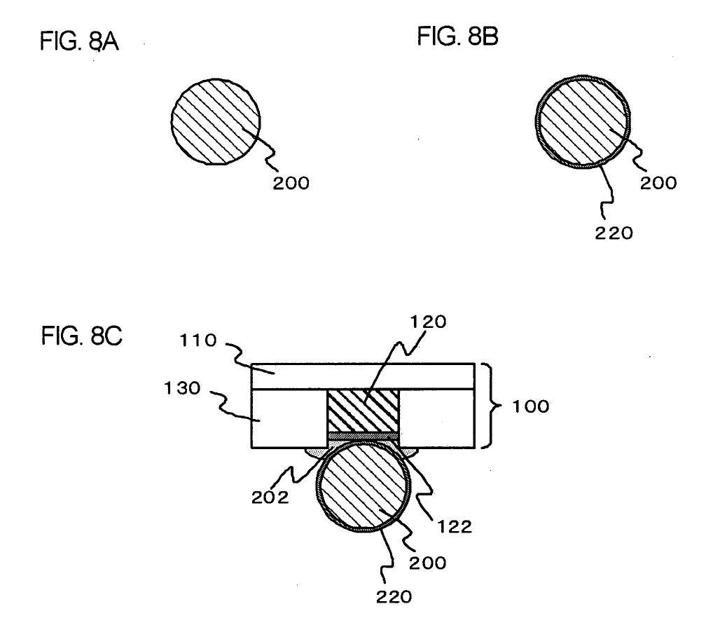

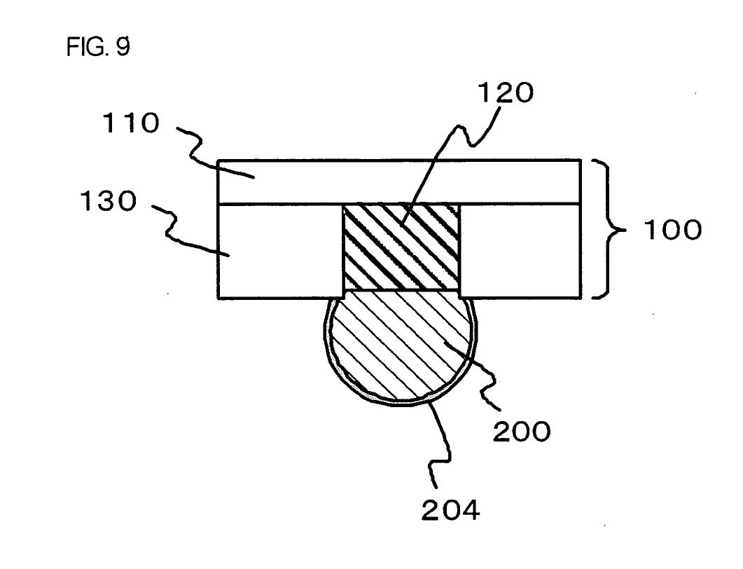

FIGS. 8A to 8C and FIG. 9 are diagrams illustrating methods of manufacturing the external connection terminal 200 and the semiconductor device according to the fourth embodiment. First, as shown in FIG. 8A, the external connection terminal 200, for example, a solder ball is manufactured. The composition of the external connection terminal 200 is the same as that of the first embodiment.

Next, as shown in FIG. 8B, the surface of the external connection terminal 200 is coated with the Au layer 220. As for the method of forming the Au layer 220 in the embodiment, an electroless plating method and an electroplating method can be considered. When the electroless plating method is used, the external connection terminal 200 is immersed in a plating solution. When the electroplating method is used, there is, for example, a method disclosed in Japanese Published patent application NO. A-H09-137295. The thickness and the weight of the Au layer 220 are the same as those of the first embodiment.

Next, as shown in FIG. 8C, the interconnect substrate 100 is prepared. A plating layer 122 is formed in the electrode pad 120 of the interconnect substrate 100. The plating layer 122 is a layer where an Ni layer and an Au layer are stacked in this order, or is a layer where an Ni layer, a Pd layer and an Au layer are stacked in this order.

Next, a flux 202 is applied to the electrode pad 120. Next, the external connection terminal 200 is attached to the electrode pad 120. Here, a plating layer 122 is not formed in electrode pad 120 of the interconnect substrate 100, a flux 202 may be directly applied to the electrode pad 120 and the external connection terminal 200 may be attached to the electrode pad 120.

Next, as shown in FIG. 9, the electrode pad 120 and the external connection terminal 200 are heated. Hereby, the external connection terminal 200 is melted, and is bonded to the electrode pad 120. At this time, there occurs the same action as the case where the external connection terminal 200 is bonded to the interconnect 310 of the circuit substrate 300 in the first embodiment.

Therefore, in the embodiment, when the external connection terminal 200 is bonded to the electrode pad 120, it is also possible to obtain the same effect as the case where the external connection terminal 200 is bonded to the interconnect 310 in the first embodiment.

For example, when the external connection terminal 200 is bonded to the electrode pad 120, the Au layer 220 is melted in the external connection terminal 200. However, in the case where the thickness of the Au layer 220 is equal to or less than 1 μm, it is possible to suppress the Au concentration of the external connection terminal 200 from becoming excessively high.

Description will be giving a specific example. The case is considered where the external connection terminal 200 is a solder ball of 0.3 μm in diameter, and the electrode pad 120 is 0.275 μm in diameter. When the Au layer of the plating layer 122 is 0.02 μm in thickness, and the Au layer 220 is 10 nm in thickness, the Au concentration of the external connection terminal 200 after bonding is 0.05 wt %. For this reason, the Au concentration of the external connection terminal 200 does not become excessively high.

As described above, although the embodiments of the invention have been set forth with reference to the drawings, they are merely illustrative of the invention, and various configurations other than those stated above can be adopted.

It is apparent that the present invention is not limited to the above embodiments, but may be modified and changed without departing from the scope and spirit of the invention.

What is claimed is:

1. A semiconductor device comprising:
an electrode pad; and
an external connection terminal connected to said electrode pad,
wherein said external connection terminal contains Sn which is equal to or more than 50 wt %, Sn and Pb which are equal to or more than 90 wt % in total or Pb which is equal to or more than 85 wt %, and the surface of said external connection terminal is coated with an Au layer.

2. The semiconductor device as set forth in claim 1, wherein the thickness of said Au layer is equal to or more than 10 nm and equal to or less than 1 μm.

3. The semiconductor device as set forth in claim 1,
wherein the weight of said Au layer is equal to or less than 0.6% of the weight of said external connection terminal.

4. The semiconductor device as set forth in claim 1,
wherein said external connection terminal contains Sn which is equal to or more than 90 wt %, Ag which is equal to or more than 1 wt % and equal to or less than 4 wt %, and Cu which is equal to or more than 0.1 wt % and equal to or less than 0.8 wt %.

5. The semiconductor device as set forth in claim 4,
wherein said external connection terminal further contains at least one of Ni which is equal to or more than 0.015 wt % and equal to or less than 0.08 wt %, and Co which is equal to or more than 0.002 wt % and equal to or less than 0.02 wt %.

6. The semiconductor device as set forth in claim 4,
wherein said external connection terminal further contains at least one of P which is equal to or more than 0.0002 wt % and equal to or less than 0.01 wt %, and Ge which is equal to or more than 0.002 wt % and equal to or less than 0.01 wt %.

7. The semiconductor device as set forth in claim 4, further comprising:
an interconnect substrate; and
a semiconductor chip mounted in one surface of said interconnect substrate,
wherein said electrode pad is formed in the other surface of said interconnect substrate.

8. The semiconductor device as set forth in claim 1, further comprising:
a semiconductor chip,
wherein said external connection terminal contains Pb which is equal to or more than 85 wt %, and
wherein said electrode pad is formed in said semiconductor chip.

9. An external connection terminal, connected to an electrode pad of an interconnect substrate or a semiconductor device, that contains:
Sn which is equal to or more than 50 wt %;
Sn and Pb which are equal to or more than 90 wt % in total; or
Pb which is equal to or more than 85 wt %,
wherein the surface of said external connection terminal is coated with an Au layer.

10. The external connection terminal as set forth in claim 9, wherein the thickness of the Au layer is equal to or more than 10 nm and equal to or less than 1 μm.

11. The external connection terminal as set forth in claim 9, wherein the weight of the Au layer is equal to or less than 0.6 wt % of said external connection terminal.

12. The external connection terminal as set forth in claim 9, wherein said external connection terminal contains Sn which is equal to or more than 90 wt %, Ag which is equal to or more than 1 wt % and equal to or less than 4 wt %, and Cu which is equal to or more than 0.1 wt % and equal to or less than 0.8 wt %.

13. The external connection terminal as set forth in claim 12, wherein said external connection terminal further contains at least one of Ni which is equal to or more than 0.015 wt % and equal to or less than 0.08 wt %, and Co which is equal to or more than 0.002 wt % and equal to or less than 0.02 wt %.

14. The external connection terminal as set forth in claim 12, wherein said external connection terminal further contains at least one of P which is equal to or more than 0.0002 wt % and equal to or less than 0.01 wt %, and Ge which is equal to or more than 0.002 wt % and equal to or less than 0.01 wt %.

15. A method of manufacturing a semiconductor device, comprising:
attaching an external connection terminal containing Sn which is equal to or more than 50 wt %, Sn and Pb which are equal to or more than 90 wt % in total, or Pb which is equal to or more than 85 wt % to an electrode pad; and
coating the surface of said external connection terminal with an Au layer.

16. The method of manufacturing the semiconductor device as set forth in claim 15, further comprising:
connecting said electrode pad with an interconnect through said external connection terminal by contacting said external connection terminal with an interconnect of a substrate and melting said external connection terminal, after said step of coating the surface of said external connection terminal with the Au layer.

17. The method of manufacturing the semiconductor device as set forth in claim 15, wherein said step of coating the surface of said external connection terminal with the Au layer is a step of forming said Au layer using plating.

18. A method of manufacturing an external connection terminal, comprising:
manufacturing the external connection terminal containing Sn which is equal to or more than 50 wt %, Sn and Pb which are equal to or more than 90 wt % in total, or Pb which is equal to or more than 85 wt %; and
coating the surface of said external connection terminal with an Au layer.

19. The method of manufacturing the external connection terminal as set forth in claim 18,
wherein said step of coating the surface of said external connection terminal with the Au layer is a step of forming said Au layer using plating.
